(19) United States
(12) Patent Application Publication
(10) Pub. No.: US 2014/0256064 A1
(43) Pub. Date: Sep. 11, 2014

(54) METHODS OF REPAIRING DAMAGED INSULATING MATERIALS BY INTRODUCING CARBON INTO THE LAYER OF INSULATING MATERIAL

(71) Applicant: GLOBALFOUNDRIES INC., Grand Cayman (KY)

(72) Inventors: William J. Taylor, JR., Clifton Park, NY (US); Nicholas V. LiCausi, Watervliet, NY (US); Errol Todd Ryan, Clifton Park, NY (US)

(73) Assignee: GLOBALFOUNDRIES Inc., Grand Cayman (KY)

(21) Appl. No.: 13/789,966

(22) Filed: Mar. 8, 2013

(51) Int. Cl. H01L 21/02

(52) U.S. Cl. CPC H01L 21/02321
USPC 438/4

(57) ABSTRACT

One illustrative method disclosed herein includes providing a layer of a carbon-containing insulating material having a nominal carbon concentration, performing at least one process operation on the carbon-containing insulating material that results in the formation of a reduced-carbon-concentration region in the layer of carbon-containing insulating material, wherein the reduced-carbon-concentration region has a carbon concentration that is less than the nominal carbon concentration, performing a carbon-introduction process operation to introduce carbon atoms into at least the reduced-carbon-concentration region and thereby define a carbon-enhanced region having a carbon concentration that is greater than the carbon concentration of the reduced-carbon-concentration region and, after introducing the carbon atoms, performing a heating process on at least the carbon-enhanced region.

### BACKGROUND OF THE INVENTION

1. Field of the Invention

Generally, the present disclosure relates to the manufacture of sophisticated semiconductor devices, and, more specifically, to various methods of repairing damaged layers of insulating materials that are formed on an integrated circuit product by introducing carbon into the layer of insulating material.

2. Description of the Related Art

The fabrication of advanced integrated circuits, such as CPUs, storage devices, ASICs (application specific integrated circuits) and the like, requires a large number of circuit elements, such as transistors, capacitors, resistors, etc., to be formed on a given chip area according to a specified circuit layout. During the fabrication of complex integrated circuits using, for instance, MOS (Metal-Oxide-Semiconductor) technology, millions of transistors, e.g., N-channel transistors (NFETs) and/or P-channel transistors (PFETs), are formed on a substrate including a crystalline semiconductor layer. A field effect transistor, irrespective of whether an NFET transistor or a PFET transistor is considered, typically includes doped source and drain regions that are formed in a semiconducting substrate and separated by a channel region. A gate insulation layer is positioned above the channel region and a conductive gate electrode is positioned above the gate insulation layer. By applying an appropriate voltage to the gate electrode, the channel region becomes conductive and current is allowed to flow from the source region to the drain region.

To improve the operating speed of field effect transistors (FETs), and to increase the density of FETs on an integrated circuit device, device designers have greatly reduced the physical size of FETs over the past decades. More specifically, the channel length of FETs has been significantly decreased, which has resulted in improving the switching speed of FETs and the overall functionality of the circuit. Further scaling (reduction in size) of the channel length of transistors is anticipated in the future. While this ongoing and continuing decrease in the channel length of transistor devices has improved the operating speed of the transistors and integrated circuits that are formed using such transistors, there are certain problems that arise with the ongoing shrinkage of feature sizes that may at least partially offset the advantages obtained by such feature size reduction. For example, as the channel length is decreased, the pitch between adjacent transistors likewise decreases, thereby increasing the density of transistors per unit area. This scaling also limits the size of the conductive contact elements and structures, which has the effect of increasing their electrical resistance. In general, the reduction in feature size and increased packing density makes everything more crowded on modern integrated circuit devices.

Typically, due to the large number of circuit elements and the required complex layout of modern integrated circuits, the electrical connections of the individual circuit elements cannot be established within the same level on which the circuit elements, such as transistors, are manufactured. Rather, modern integrated circuit products have multiple so-called metallization layer levels that, collectively, contain the “wiring” pattern for the product, i.e., the conductive structures that provide electrical connection to the transistors and the circuits, such as conductive vias and conductive metal lines. In general, the conductive metal lines are used to provide intra-level (same level) electrical connections, while inter-level (between levels) connections or vertical connections are referred to as vias. In short, the vertically oriented conductive via structures provide the electrical connection between the various stacked metallization layers. Accordingly, the electrical resistance of such conductive structures, e.g., lines and vias, becomes a significant issue in the overall design of an integrated circuit product, since the cross-sectional area of these elements is correspondingly decreased, which may have a significant influence on the effective electrical resistance and overall performance of the final product or circuit.

Improving the functionality and performance capability of various metallization systems has also become an important aspect of designing modern semiconductor devices. One example of such improvements is reflected in the increased use of copper metallization systems in integrated circuit devices and the use of so-called “ultra-low-k” (ULK) dielectric materials (materials having a dielectric constant less than about 3) in such devices. The use of ULK dielectric materials tends to improve the signal-to-noise ratio (S/N ratio) by reducing crosstalk as compared to other dielectric materials with higher dielectric constants.

However, the use of such ULK dielectric materials can be problematic as they tend to be relatively porous and generally have poorer mechanical strength as compared to other insulating materials having a higher k-value, e.g., silicon dioxide. Moreover, there is an increased discrepancy between the k-values of ULK dielectric materials that have been subjected to various processing operations and the pristine, as-initially-deposited ULK dielectric materials, with the ULK materials that were subjected to processing operations having an increased or higher k-value. In general, ULK dielectric materials with one or more regions of increased k-value are said to be “damaged” in the sense that the k-value in at least certain regions of the ULK material is greater than that of the pristine ULK material at the time it was formed. Such an increase in the k-value of ULK materials, even in cases where it may be somewhat localized, is undesirable as it reduces the effectiveness of the ULK material. Fundamentally, the damage to such ULK materials is a result of a reduction in the amount of carbon present in the affected regions in the ULK material. In one situation, such damage has been attributed to the presence of moisture and adsorbed chemicals (slurries, cleaning solutions, silanol, etc.) penetrating the porous network of such ULK materials during a chemical mechanical polishing (CMP) process, and the resulting chemical interactions that occur. FIG. 1A schematically and simplistically depicts an illustrative layer of ULK material 12 having a carbon-depleted, damaged region 14 formed therein as a result of the performance of one or more process operations, e.g., the performance of a CMP process. The thickness or depth of the carbon-depleted, damaged region 14 may vary depending upon a variety of factors. In some cases, the carbon-depleted, damaged region 14 may have a depth or thickness that falls within the range of about 10-50 nm. Once enough of the carbon has been removed, the damaged ULK material tends to rehydroxylate and hydrogen bonds with water. Because water has a dielectric constant of about 70, small amounts of water that are present in the ULK material cause the k-value of the damaged ULK material to increase, sometimes significantly. In some cases, carbon depletion may cause the ULK material to exhibit some other undesirable film properties, e.g., like relatively poor Time Dependent Dielectric Breakdown (TDDB) properties. Other process operations that may cause such carbon depletion damage include reactive ion etching processes that are commonly performed to etch trenches or vias in a layer of ULK material, exposure to plasma-based processing operations, such as so-called “ashing,” a process that is typically performed to remove patterned photoresist masks used in etching and ion implantation processes. Some cleaning solutions may have chemistries that can also lead to the reduction of carbon in a ULK material.

Ideally, prior to proceeding with additional processing operations, the k-value of the carbon-depleted, damaged region 14 should be restored, as much as possible, to its pristine (as-deposited) k-value. In some cases, a thermal treatment, such as UV annealing, is performed in an attempt to remove the moisture present within the damaged ULK material. In other cases, a silylation process may be performed in an attempt to repair the damaged ULK material, i.e., remove adsorbed moisture (and —OH groups) and replace them with methyl groups (—CH₃). In general, a silylation process involves exposing the damaged region, e.g., region 14, to a silylating agent in liquid or gas form for a period sufficient to complete the reaction with the damaged region 14 in the ULK material. Such a silylation process 16 is schematically depicted in FIG. 1B. The silylation process 16 results in the formation of a treated region of ULK material 16A in the ULK material 12. FIG. 1C depicts the device after the silylation and annealing process has been performed wherein the k-value of the treated ULK material 16A is effectively decreased in comparison to the damaged region 14. However, the k-value of this repaired region 16A is typically not decreased to such a level that it matches the k-value of the pristine, undamaged ULK material 12. Unfortunately, the depth of the treated ULK material 16A is typically very shallow, e.g., 2 nm or less, due to difficulty in diffusing the treating agent, i.e., the repair precursor, to any significant depth into the ULK material 12. As can be seen in FIG. 1C, while the uppermost portion of the damaged region 14 has been repaired, i.e., the k-value of this region remains higher than that of the pristine, undamaged ULK material 12, there still remains a significant amount of the damaged region 14 in the ULK material 12 after the treatment process was performed. The presence of this remaining damaged region 14 can adversely affect device performance.

The present disclosure is directed to methods of repairing damaged layers of insulating materials that are formed on an integrated circuit product by introducing carbon into the layer of insulating material that may solve or at least reduce some of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to methods of repairing damaged layers of insulating materials that are formed on an integrated circuit product by introducing carbon into the layer of insulating material. One illustrative method disclosed herein includes providing a layer of a carbon-containing insulating material having a nominal carbon concentration, performing at least one process operation on the carbon-containing insulating material that results in the formation of a reduced-carbon-concentration region in the layer of carbon-containing insulating material, wherein the reduced-carbon-concentration region has a carbon concentration that is less than the nominal carbon concentration, performing a carbon-introduction process operation to introduce carbon atoms into at least the reduced-carbon-concentration region and thereby define a carbon-enhanced region having a carbon concentration that is greater than the carbon concentration of the reduced-carbon-concentration region and, after introducing the carbon atoms, performing a heating process on the carbon-containing insulating material.

Another illustrative method disclosed herein includes providing a layer of a carbon-containing insulating material having a nominal carbon concentration, performing at least one process operation on the carbon-containing insulating material that results in the formation of a reduced-carbon-concentration region in the layer of carbon-containing insulating material, wherein the reduced-carbon-concentration region has a carbon concentration that is less than the nominal carbon concentration, performing a carbon-introduction process operation to introduce carbon atoms into at least the reduced-carbon-concentration region and thereby define a carbon-enhanced region having a carbon concentration that is equal to or greater than the nominal carbon concentration and, after introducing the carbon atoms, performing a heating process at a temperature that is less than 400° C. on the carbon-containing insulating material.

One illustrative method disclosed herein includes providing a layer of a carbon-containing insulating material having a nominal carbon concentration, performing at least one process operation on the carbon-containing insulating material that results in the formation of a reduced-carbon-concentration region in the layer of carbon-containing insulating material, wherein the reduced-carbon-concentration region has a first depth and a carbon concentration that is less than the nominal carbon concentration, performing a carbon-introduction process operation to introduce carbon atoms into at least the reduced-carbon-concentration region and define a carbon-enhanced region having a second depth and a carbon concentration that is greater than the carbon concentration of the reduced-carbon-concentration region, wherein the second depth is greater than the first depth, and, after introducing the carbon atoms, performing a heating process at a temperature that is less than 400° C. on the carbon-containing insulating material.

Yet another illustrative method disclosed herein includes providing a layer of a carbon-containing insulating material having a nominal carbon concentration, performing a carbon-introduction process operation to introduce carbon atoms into the carbon-containing insulating material and thereby define a carbon-enhanced region having a carbon concentration that is equal to or greater than the nominal carbon concentration of the carbon-containing insulating material, after forming said carbon-enhanced region, performing at least one process operation on the carbon-containing insulating material that results in the formation of a reduced-carbon-concentration region in the layer of carbon-containing insulating material, wherein the reduced-carbon-concentration region is positioned entirely within the carbon-enhanced region, and, after forming the reduced-carbon-concentration region, performing a heating process on the carbon-containing insulating material.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1C depict an illustrative prior art method of attempting to repair a damaged layer of insulating material;

FIGS. 2A-2L depict various novel methods disclosed herein for repairing damaged layers of insulating materials by introducing carbon into the layer of insulating material; and

FIGS. 3A-3C depict other novel methods disclosed herein for repairing damaged layers of insulating materials by introducing carbon into the layer of insulating material.

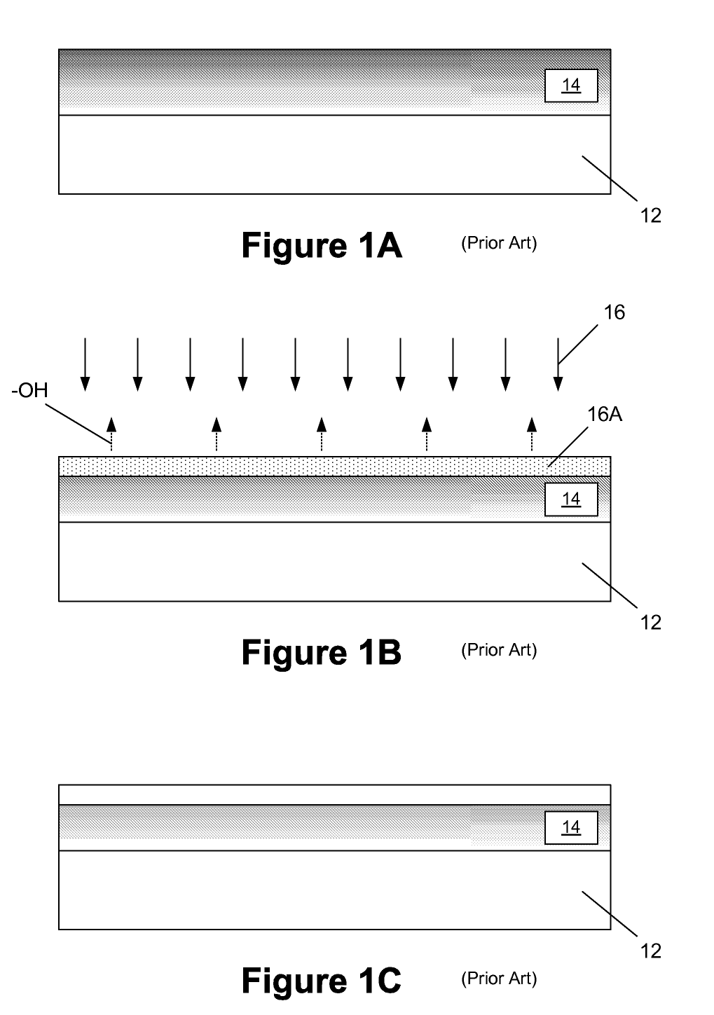

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to methods of repairing damaged layers of insulating materials that are formed on an integrated circuit product by introducing carbon into the layer of insulating material. As will be readily apparent to those skilled in the art upon a complete reading of the present application, the present method is applicable to a variety of technologies, e.g., NFET, PFET, CMOS, etc., and is readily applicable to a variety of devices, including, but not limited to, ASIC's, logic devices, memory devices, etc. With reference to the attached drawings, various illustrative embodiments of the methods disclosed herein will now be described in more detail.

In general, the methods disclosed herein are directed to repairing damaged regions in a layer of insulating material by introducing carbon into the layer of insulating material after or before the damage has occurred. As used herein, “damaged” means a region of an insulating material layer having a k-value (dielectric constant) that is greater than the k-value of the pristine insulating material layer as it is initially deposited. As noted previously, the damage to such insulating material layers is primarily a result of a reduction in the amount of carbon present in the affected regions in the insulating material layer. Such insulating material layers may be damaged by being subjected to one or more process operations, e.g., a CMP process, reactive ion etching (RIE) processes, exposure to plasma-based processing operations, such as a so-called ashing process that is typically performed to remove a patterned photoresist mask, etc.

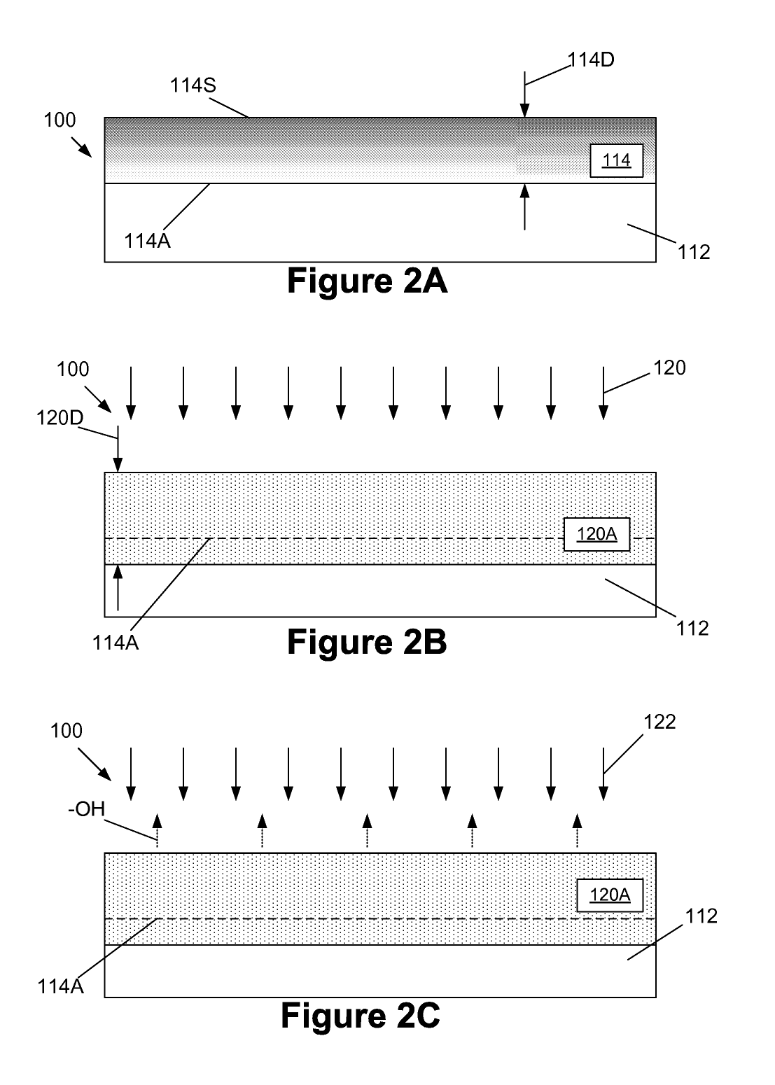

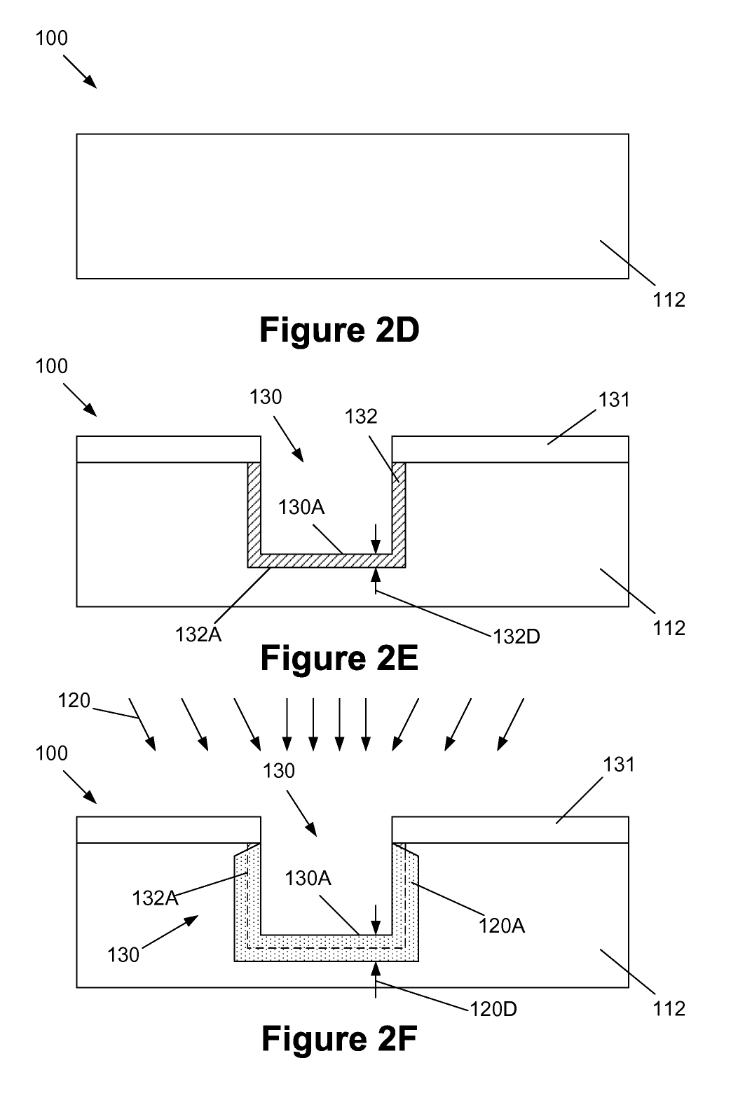

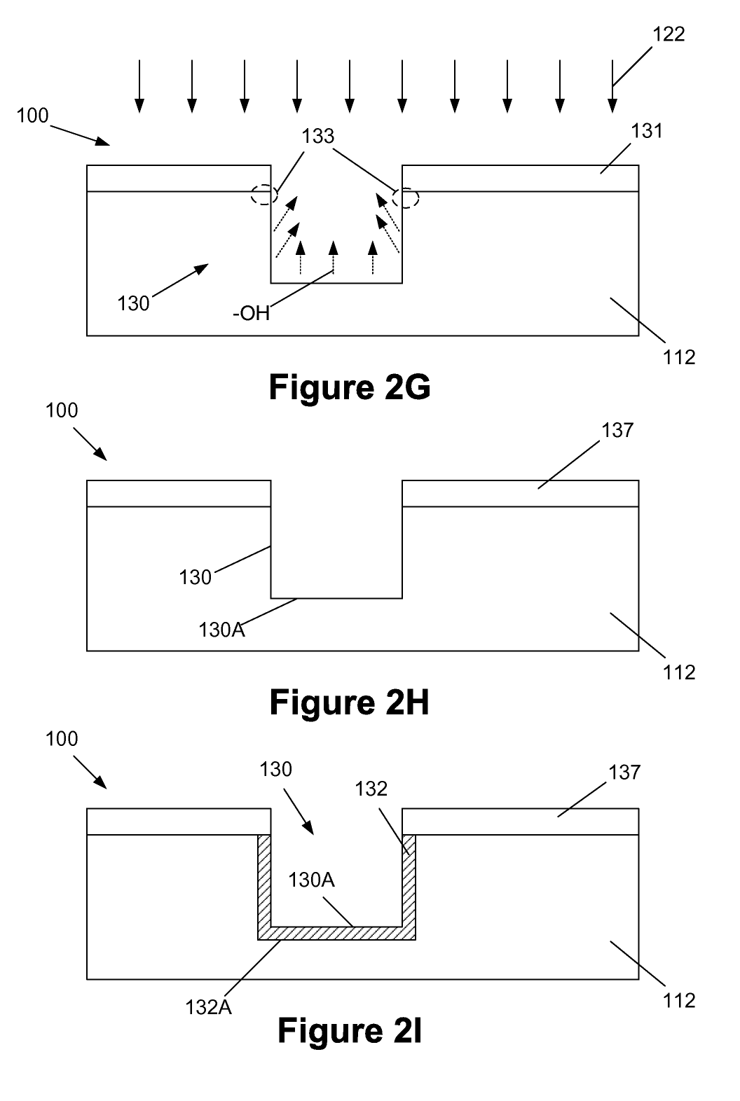

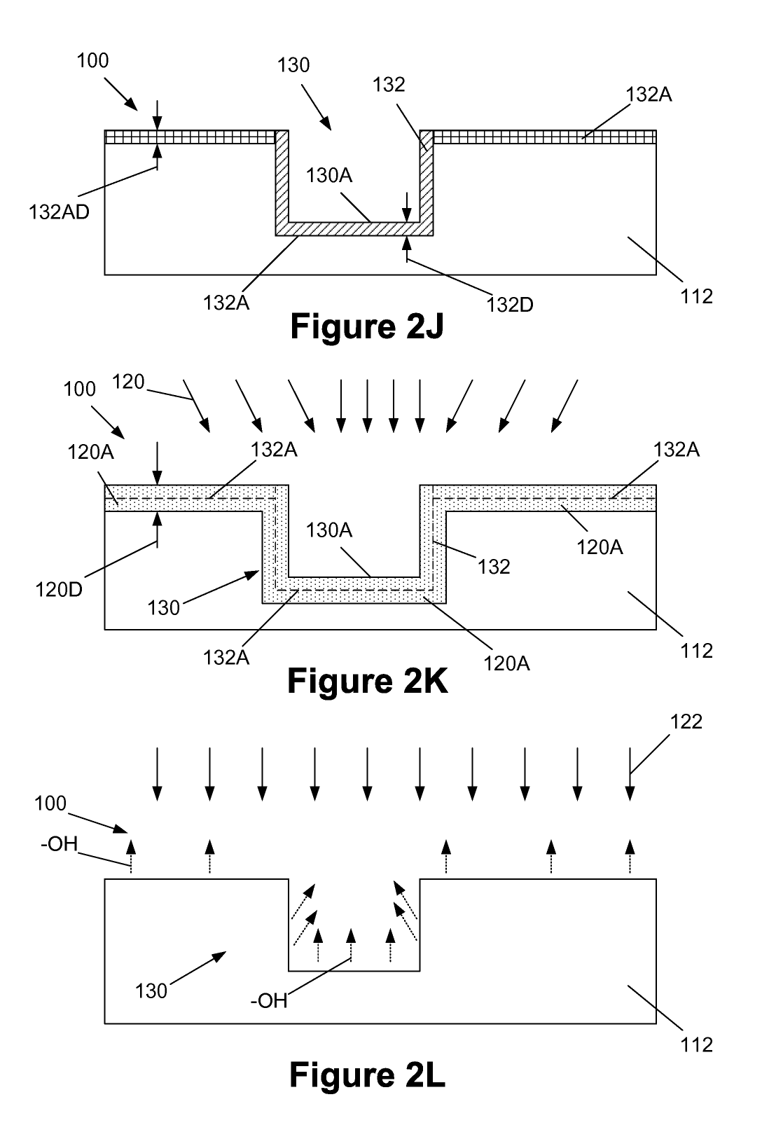

FIG. 2A is a simplified view of an illustrative integrated circuit device 100 at an early stage of manufacturing that is formed above a semiconductor substrate (not shown). The substrate may have a variety of configurations, such as a bulk substrate configuration, an SOI (silicon-on-insulator) configuration, and it may be made of materials other than silicon. Thus, the terms “substrate” or “semiconductor substrate” should be understood to cover all semiconducting materials and all forms of such materials. The device 100 may be any type of integrated circuit device. Also depicted in FIG. 2A are an illustrative insulating material layer 112 and a schematically depicted damaged region 114 having a depth 114D. The damaged region 114 is the result of performing at least one process operation where the insulating material layer 112 was exposed to the process operation. In some cases, the depth 114D of the damaged region 114 may be on the order of about 10-60 nm. The amount of damage, i.e., the amount of carbon depletion, will typically decrease with depth into the insulating material layer 112. Simply put, portions of the damaged region 114 near the bottom 114A of the damaged region 114 will suffer less carbon loss than the portion of the damaged region 114 near the surface 114S. However, in some cases, depending upon the depth 114D of the damaged region 114, the carbon depletion may be substantially uniform throughout the depth 114D of the damaged region 114.

The insulating material layer 112 may be formed as part of one or more metallization layers that are formed for the integrated circuit product 100, and it may be formed at any level or location on the integrated circuit product 100. In some cases, a plurality of conductive structures (not shown), e.g., conductive lines/vias, may be formed in the insulating material layer 112. The insulating material layer 112 may be comprised of any carbon-containing insulating material. In one embodiment, the insulating material layer 112 may be a carbon-containing ULK insulating material layer having a k-value less than approximately 3, e.g., SiCOH, porous SiCOH, spin-on organosilicate glass, etc. The nominal or pristine carbon content of the insulating material layer 112, as deposited, may vary depending upon the material selected. The damaged region 114 has a reduced-carbon-concentration relative to the nominal carbon concentration of the insulating material layer 112. In some cases, depending upon a variety of factors, the carbon concentration in the damaged, reduced-carbon-concentration region 114 may be about 5-30% less than the nominal carbon concentration of the insulating material layer 112. The insulating material layer 112 may be formed by performing a variety of known processing techniques, such as a chemical vapor deposition (CVD) process, an atomic layer deposition (ALD) process, and the thickness of the insulating material layer 112 may vary depending upon the particular application.

As shown in FIG. 2B, one illustrative method disclosed herein for repairing the damaged region 114 involves performing a carbon-introduction process operation 120 to introduce carbon atoms into at least the reduced-carbon-concentration damaged region 114 and thereby define a carbon-enhanced region 120A. In some applications, the carbon-introduction process operation 120 is performed under such conditions that the resulting carbon-enhanced region 120A has a carbon concentration that is greater than the carbon concentration of the reduced-carbon-concentration damaged region 114. In other cases, the carbon-introduction process operation 120 may be performed under conditions such that the carbon concentration of the resulting carbon-enhanced region 120A may be less than, approximately equal to or greater than the nominal carbon concentration of the insulating material layer 112. The depth 120D of the carbon-enhanced region 120A may vary depending upon the particular application and the nature of the damage done to the insulating material layer 112, e.g., the depth 120D may fall within the range of about 1-70 nm. In one particular embodiment, the carbon-introduction process operation 120 is performed under conditions such that depth 120D of the carbon-enhanced region 120A is greater than the depth 114A of the damaged region 114, i.e., the damaged region 114 is positioned entirely within the carbon-enhanced region 120A.

In one illustrative embodiment, the carbon-introduction process operation 120 may be a plasma doping process or it may be comprised of one or more ion implantation processes. In the case where the carbon-introduction process operation 120 comprises performing one or more ion implantation processes, the carbon dosage used during the implantation process may fall within the range of about 1e¹⁴-1e¹⁶ atoms/cm², and it may be performed at an energy level that falls within the range of about 1-5 keV. Depending upon the particular application, the ion implantation process(es) may be angled or substantially vertically oriented ion implantation processes.

Next, as shown in FIG. 2C, one or more heating process(es) 122 are performed on the device 100. In one illustrative example, the heating process 122 may be performed at a temperature of less than 400° C. for a duration of about 30 seconds to 10 minutes (the duration varies depending upon the heating method) in an inert ambient. The heating process 122 may be performed using any of a variety of known techniques and equipment, e.g., a traditional furnace, an RTA chamber, or it may be a UV or E-beam based heating process. The heating process(es) 122 promote carbon linking within the structure of the insulating material layer 112 to thereby replenish some or all of the carbon that was removed from the insulating material layer 112 when the damaged region 114 was created. As depicted in FIG. 2C, during the heating process 122, moisture and silanol (—OH) are driven from the damaged region 114 of the insulating material layer 112 via condensation reactions that generate water (H₂O) that leaves the material. The heating process 122 causes the replacement of enough carbon in the damaged region 114 such that the carbon content of the repaired portions of the insulating material layer 112 is greater than the carbon content of the damaged region 114. Accordingly, the k-value of the repaired regions of the insulating material layer 112 is less than that of the initially damaged region 114. In one particular embodiment, the carbon-introduction process operation 120 and the heating process 122 are performed under conditions such that the carbon content in the damaged region 114 is restored to approximately the same as the nominal carbon content in the pristine insulating material layer 112, as reflected by the absence of the original damaged region 114 in FIG. 2D. While the damaged region may be repaired using the methods disclosed herein, it is not necessarily the case that the damaged region will be repaired to its pristine, pre-damaged condition.

FIGS. 2E-2G depict a more specific example of one illustrative method disclosed herein. FIG. 2E depicts the device 100 after an etching process, such as a reactive ion etching process, was performed on the insulating material layer 112 through a patterned hard mask layer 131, e.g., a silicon nitride hard mask, to define an illustrative opening 130 in the insulating material layer 112. As a result of the etching process, a damaged, reduced-carbon-concentration region 132 is formed in the insulating material layer 112 adjacent the perimeter defined by the opening 130. The damaged region 132 has a bottom 132A and a depth 132D that may have the same approximate dimensions as those discussed above with respect to the depth 114D of the damaged region 114. The opening 130 is intended to be representative of any type of opening formed in any type of insulating material wherein a conductive structure, e.g., a copper-based structure, may thereafter be formed. The opening 130 may be of any desired shape, depth or configuration. In the depicted example, the opening 130 is a classic trench that has a bottom surface 130A. In other embodiments, the opening 130 may be a through-hole type feature, e.g., a classic via, that extends all of the way through the layer of insulating material 112 and exposes an underlying layer of material or an underlying conductive structure (not shown), such as an underlying metal line. Thus, the shape, size, depth or configuration of the opening 130 should not be considered to be a limitation of the present inventions.

Next, as shown in FIG. 2F, the above-described carbon-introduction process operation 120 is performed on the exposed portions of the opening 130 to thereby form the carbon-enhanced region 120A described above. Note that, in this example, the carbon-introduction process operation 120 is comprised of a vertically oriented ion implantation process and a plurality of angled ion implantation processes to insure that the sidewalls of the opening 130 are treated. Due to the angled implantation process, small regions of the damaged region 132A just under the mask layer 132 may not be implanted with additional carbon atoms. However, this process operation could also be performed using other processes, such as, for example, a plasma doping process.

Next, as shown in FIG. 2G, one or more of the above-described heating processes 122 are performed on the device 100. As before, the heating process(es) 122 promote carbon linking within the structure of the insulating material layer 112 to thereby replenish some or all of the carbon that was removed from the insulating material layer 112 when the damaged region 132 was created. As depicted in FIG. 2G, during the heating process 122, moisture and silanol (—OH) are driven from the damaged region 132 of the insulating material layer 112 via condensation reactions that generate water (H₂O) that leaves the material. In some situations, due to the geometry of the opening 130 and the nature of the angled ion implantation process, the areas within the dashed lines 133 may or may not be completely treated. By using the methods described herein, the k-value of the repaired regions of the insulating material layer 112 adjacent the opening 130 is less than that of the initially damaged region 132. In one particular embodiment, the carbon content in the damaged region 132 is restored to approximately the same as the nominal carbon content in the pristine insulating material layer 112, as reflected by the absence of the damaged region 132 in FIG. 2H.

FIGS. 2I-2L depict another specific example of one illustrative method disclosed herein. FIG. 2I depicts the device 100 after the above-described damaged region 132 has been formed in the insulating material layer 112 by etching the opening 130. In this example, the etching was performed through a patterned photoresist mask layer 137 that was formed directly on the insulating material layer 112. FIG. 2J depicts the device 100 after an ashing process was performed to remove the patterned photoresist mask layer 137. As a result of the ashing process, damaged, reduced-carbon-concentration regions 132A are formed near the upper surface of the insulating material layer 112. The ashing process may also result in additional damage in the area of the opening 130, but such additional damage adjacent the opening 130 is not depicted in FIG. 2J. The damaged region 132A has a depth 132AD that may have the same approximate dimensions as those discussed above with respect to the depth 114D of the damaged region 114.

Next, as shown in FIG. 2K, the above-described carbon-introduction process operation 120 is performed on the exposed portions of the opening 130 and the exposed upper surface of the insulating material layer 112 to thereby form the carbon-enhanced region 120A described above. Note that, in this example, the carbon-introduction process operation 120 is again comprised of a vertically oriented ion implantation process and a plurality of angled ion implantation processes to insure that the sidewalls of the opening 130 are treated.

Next, as shown in FIG. 2L, one or more of the above-described heating processes 122 are performed on the device 100. As before, the heating process(es) 122 promote carbon linking within the structure of the insulating material layer 112 to thereby replenish some or all of the carbon that was removed from the insulating material layer 112 when the damaged regions 132, 132A were created. As depicted in FIG. 2L, during the heating process 122, moisture and silanol (—OH) are driven from the damaged regions 132, 132A of the insulating material layer 112 via condensation reactions that generate water (H₂O) that leaves the material. In one particular embodiment, the carbon content in the damaged regions 132, 132A are restored to approximately the same as the nominal carbon content in the pristine insulating material layer 112, as reflected by the absence of the damaged regions 132, 132A in FIG. 2L.

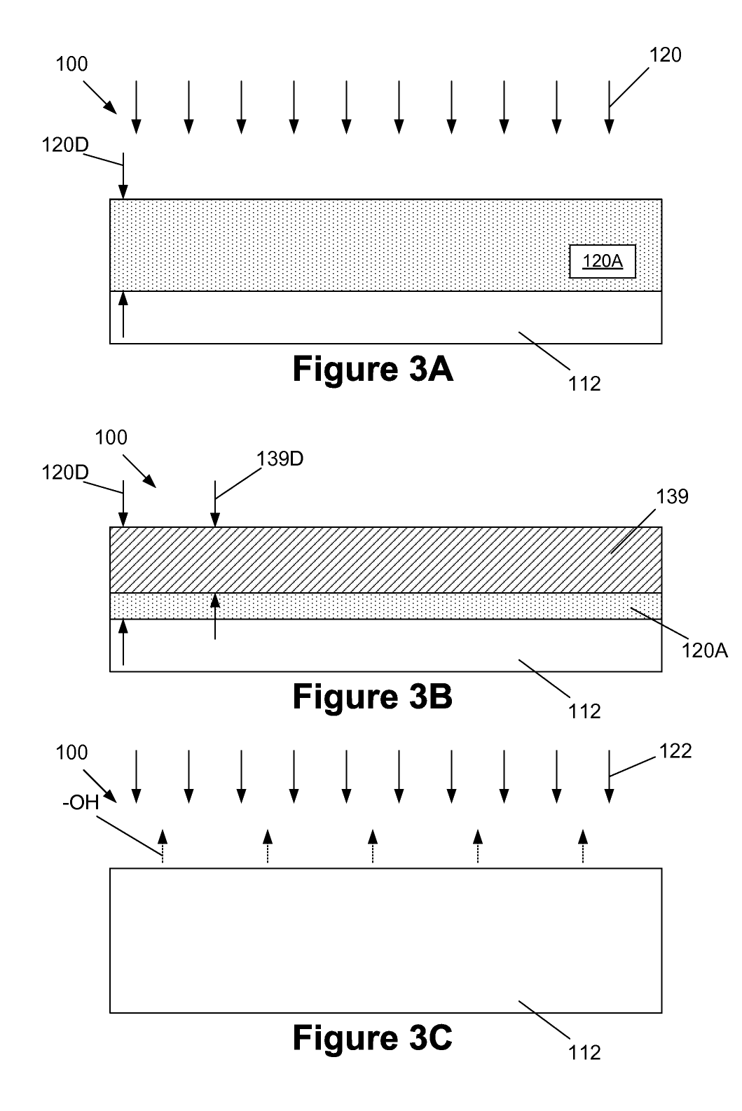

FIGS. 3A-3C depict yet another novel method disclosed herein for repairing damaged layers of insulating materials by introducing carbon into the layer of insulating material. In general, in this particular embodiment, the carbon-introduction process operation 120 is performed on the insulating material layer 112 prior to the insulating material layer 112 being damaged, i.e., prior to having the carbon content of a region of the insulating material layer 112 reduced by performing a process operation. As shown in FIG. 3A, in this embodiment, the method involved performing the above-described carbon-introduction process operation 120 on the undamaged insulating material layer 112 to thereby form the carbon-enhanced region 120A described above. The depth 120D of the implant region 120A is selected based upon the anticipated depth to which the insulating material layer 112 may be damaged during one or more processing operations that are to be subsequently performed.

FIG. 3B depicts the device 100 after a process operation, e.g., a CMP process, was performed on the insulating material layer 112. As a result of the process operation, a damaged, reduced-carbon-concentration region 139 was formed near the upper surface of the insulating material layer 112. The damaged region 139 has a depth 139D that may have the same approximate dimension as discussed above with respect to the depth 114D of the damaged region 114.

Next, as shown in FIG. 3C, one or more of the above-described heating processes 122 are performed on the device 100. As before, the heating process(es) 122 promote carbon linking within the structure of the insulating material layer 112 to thereby replenish some or all of the carbon that was removed from the insulating material layer 112 when the damaged region 139 was created. In one particular embodiment, the carbon content in the damaged region 139 is restored to approximately the same as the nominal carbon content in the pristine insulating material layer 112, as reflected by the absence of the damaged region 139 in FIG. 3C.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
providing a layer of a carbon-containing insulating material having a nominal carbon concentration;
performing at least one process operation on said carbon-containing insulating material that results in the formation of a reduced-carbon-concentration region in said layer of carbon-containing insulating material, wherein said reduced-carbon-concentration region has a carbon concentration that is less than said nominal carbon concentration;
performing a carbon-introduction process operation to introduce carbon atoms into at least said reduced-carbon-concentration region and thereby define a carbon-enhanced region having a carbon concentration that is greater than said carbon concentration of said reduced-carbon-concentration region; and
after introducing said carbon atoms, performing a heating process on said carbon-containing insulating material.

2. The method of claim 1, wherein said carbon-containing insulating material is comprised of an insulating material having a k-value less than 3.

3. The method of claim 1, wherein performing said at least one process operation on said carbon-containing insulating material comprises performing one of an etching process, a chemical mechanical polishing process or a photoresist removal process so as to thereby form said reduced-carbon-concentration region.

4. The method of claim 1, wherein performing said carbon-introduction process operation comprises performing at least one ion implantation process or performing a plasma doping process.

5. The method of claim 1, wherein performing said carbon-introduction process operation comprises performing at least one ion implantation process using a dopant dose of carbon that falls within the range of 10e¹⁴-10e¹⁶ atoms/cm².

6. The method of claim 5, wherein performing said at least one ion implantation process comprises performing at least one angled ion implantation process.

7. The method of claim 1, wherein performing said carbon-introduction process operation comprises performing said carbon-introduction process operation such that said carbon-enhanced region has a carbon concentration that is less than, equal to or greater than said nominal carbon concentration.

8. The method of claim 1, wherein said reduced-carbon-concentration region has a first depth and said carbon-enhanced region has a second depth, wherein said second depth is greater than said first depth.

9. The method of claim 1, wherein said reduced-carbon-concentration-region is positioned entirely within said carbon-enhanced region.

10. The method of claim 1, wherein said heating process is performed at a temperature that is less than 400° C.

11. A method, comprising:
providing a layer of a carbon-containing insulating material having a nominal carbon concentration;
performing at least one process operation on said carbon-containing insulating material that results in the formation of a reduced-carbon-concentration region in said layer of carbon-containing insulating material, wherein said reduced-carbon-concentration region has a carbon concentration that is less than said nominal carbon concentration;
performing a carbon-introduction process operation to introduce carbon atoms into at least said reduced-carbon-concentration region and thereby define a carbon-enhanced region having a carbon concentration that is less than, equal to or greater than said nominal carbon concentration; and
after introducing said carbon atoms, performing a heating process on said carbon-containing insulating material, wherein said heating process is performed at a temperature that is less than 400° C.

12. The method of claim 11, wherein said carbon-containing insulating material is comprised of an insulating material having a k-value less than 3.

13. The method of claim 11, wherein performing said carbon-introduction process operation comprises performing at least one ion implantation process or performing a plasma doping process.

14. The method of claim 11, wherein performing said carbon-introduction process operation comprises performing at least one ion implantation process using a dopant dose of carbon that falls within the range of 10e¹⁴-10e¹⁶ atoms/cm².

15. The method of claim 14, wherein performing said at least one ion implantation process comprises performing at least one angled ion implantation process.

16. The method of claim 11, wherein said reduced-carbon-concentration region has a first depth and said carbon-enhanced region has a second depth, wherein said second depth is greater than said first depth.

17. The method of claim 11, wherein said reduced-carbon-concentration region is positioned entirely within said carbon-enhanced region.

18. A method, comprising:
providing a layer of a carbon-containing insulating material having a nominal carbon concentration;
performing at least one process operation on said carbon-containing insulating material that results in the formation of a reduced-carbon-concentration region in said layer of carbon-containing insulating material, wherein said reduced-carbon-concentration region has a first depth and a carbon concentration that is less than said nominal carbon concentration;
performing a carbon-introduction process operation to introduce carbon atoms into at least said reduced-carbon-concentration region and thereby define a carbon-enhanced region having a second depth and a carbon concentration that is greater than said carbon concentration of said reduced-carbon-concentration region, wherein said second depth is greater than said first depth; and
after introducing said carbon atoms, performing a heating process on said carbon-containing insulating material, wherein said heating process is performed at a temperature that is less than 400° C.

19. The method of claim 18, wherein said carbon-containing insulating material is comprised of an insulating material having a k-value less than 3.

20. The method of claim 18, wherein performing said carbon-introduction process operation comprises performing at least one ion implantation process or performing a plasma doping process.

21. The method of claim 18, wherein performing said carbon-introduction process operation comprises performing at least one ion implantation process using a dopant dose of carbon that falls within the range of 10e¹⁴-10e¹⁶ atoms/cm².

22. The method of claim 21, wherein performing said at least one ion implantation process comprises performing at least one angled ion implantation process.

23. The method of claim 18, wherein performing said carbon-introduction process operation comprises performing said carbon-introduction process operation such that said carbon-enhanced region has a carbon concentration that is equal to or greater than said nominal carbon concentration.

24. The method of claim 18, wherein said reduced-carbon-concentration region is positioned entirely within said carbon-enhanced region.

25. A method, comprising:
providing a layer of a carbon-containing insulating material having a nominal carbon concentration;
performing a carbon-introduction process operation to introduce carbon atoms into said carbon-containing insulating material and thereby define a carbon-enhanced region having a carbon concentration that is greater than said nominal carbon concentration of said carbon-containing insulating material;
after forming said carbon-enhanced region, performing at least one process operation on said carbon-containing insulating material that results in the formation of a reduced-carbon-concentration region in said layer of carbon-containing insulating material, wherein said reduced-carbon-concentration region is positioned entirely within said carbon-enhanced region; and
after forming said reduced-carbon-concentration region, performing a heating process on said carbon-containing insulating material.

26. The method of claim 25, wherein said carbon-containing insulating material is comprised of an insulating material having a k-value less than 3.

27. The method of claim 25, wherein performing said carbon-introduction process operation comprises performing at least one ion implantation process or performing a plasma doping process.

28. The method of claim 25, wherein performing said carbon-introduction process operation comprises performing at least one ion implantation process using a dopant dose of carbon that falls within the range of 10e¹⁴-10e¹⁶ atoms/cm².

29. The method of claim 25, wherein said carbon-enhanced region has a first depth and said reduced-carbon-concentration region has a second depth, wherein said second depth is less than said first depth.
